(19) United States
(12) Patent Application Publication
(10) Pub. No.: US 2016/0072062 A1
(43) Pub. Date: Mar. 10, 2016

(54) AL-W-O STACK STRUCTURE APPLICABLE TO RESISTIVE RANDOM ACCESS MEMORY

(71) Applicant: TSINGHUA UNIVERSITY, Beijing (CN)

(72) Inventors: Huaqiang WU, Beijing (CN); Yue BAI, Beijing (CN); Minghao WU, Beijing (CN); He QIAN, Beijing (CN)

(73) Assignee: TSINGHUA UNIVERSITY, Beijing (CN)

(21) Appl. No.: 14/758,463

(22) PCT Filed: May 27, 2014
(86) PCT No.: PCT/CN2014/078496

§ 371 Date: Jun. 29, 2015

(30) Foreign Application Priority Data
May 28, 2013 (CN) 201310204621.7

(51) Int. Cl. H01L 45/00

(52) U.S. Cl. CPC H01L 45/146; H01L 45/085; H01L 45/1233; H01L 45/1253

(57) ABSTRACT

An Al-W-O stack structure applicable to a resistive random access memory according to an embodiment of the invention comprises a tungsten top electrode, a tungsten oxide layer formed on the tungsten lower electrode, an aluminum oxide layer formed on the tungsten oxide layer and an aluminum top electrode formed on the aluminum oxide layer. The invention utilizes the different properties of two metals, namely aluminum and tungsten in bonding with oxygen ions, to obtain a resistive random access memory with more stable performances, lower power consumption and larger high resistance-low resistance ratio.

### CROSS-REFERENCE TO RELATED APPLICATIONS

The present application is a national filing in the U.S. Patent & Trademark Office of PCT/CN2014/078496 filed May 27, 2014, and claims priority of Chinese Patent Application No. 201310204621.7 filed May 28, 2013, both of which applications are incorporated herein in their entireties by this reference.

### FIELD OF THE INVENTION

The invention belongs to semiconductor manufacturing technologies, in particular to an Al-W-O stack structure applicable to a resistive random access memory.

### BACKGROUND OF THE INVENTION

Along with continuous development of semiconductor technologies and further popularization of electronic equipment in society, especially the popularization of portable electronics, such as mobile phones, and the development of special electronic equipment, such as medical instruments, the sizes of microelectronics are continuously reduced. Meanwhile, the development of video and music entertainment causes the data size increases constantly, which further causes the applications of memories, especially non-volatile memories become more and more important. In the current society, FLASH memories definitely dominate in the non-volatile memories. However, along with the situation that the sizes of the microelectronics become below deep nanometer, a large number of defects of the traditional FLASH memories arise. On the other hand, novel resistive random access memories (RRAM) have many advantages, including good scaling performance, convenience for 3D stacking, simple structure, high memory density, low operation voltage, small operation current, high speed in reading and writing, low power consumption, compatibility with traditional CMOS (complementary metal oxide semiconductors) and so on. The novel resistive random access memories (RRAM) are of sandwich structure filled with one-element or multi-element metal oxides between upper electrodes and lower electrodes, wherein the filled one-element or multi-element metal oxide layers are resistive switching layers. The mechanism is that according to the different voltages applicable to the structure, the resistances of the resistive switching layers change correspondingly in high resistive state and low resistive state to open or block current flow channels, and the significant difference between the high resistance state and the low resistance state is utilized for storing information.

The novel resistive random access memories have excellent performances. Their performances are closely associated with the material selection and the structure composition of resistive switching layers. Research groups around the world are trying to develop new materials, new combinations and new structures to improve the performances of the resistive random access memories. The operation voltage, the high resistance-low resistance ratio, the number of write-erase cycles and other performances of the resistive random access memories can be improved by selecting different material combinations.

### SUMMARY OF THE INVENTION

The invention intends to at least solve one of the aforementioned technical problems to some extent or at least provide a useful business option. Therefore, one object of the invention is to provide an Al-W-O stack structure applicable to a resistive random access memory, which has the advantages of more stable performances, lower power consumption and larger high resistance-low resistance ratio.

According to an embodiment of the invention the Al-W-O stack structure applicable to the resistive random access memory includes a tungsten bottom electrode, a tungsten oxide layer formed on the tungsten bottom electrode, an aluminum oxide layer formed on the tungsten oxide layer and an aluminum top electrode formed on the aluminum oxide layer.

In one embodiment of the invention, the tungsten oxide layer is formed in a thermal oxidation method.

In one embodiment of the invention, the thickness of the tungsten oxide layer is 30-70 nm.

In one embodiment of the invention, the aluminum oxide layer is formed in a contact type oxidation method.

In one embodiment of the invention, the temperature of contact type oxidation is 400-500° C., and the time of contact type oxidation is 50-200 s.

In one embodiment of the invention, the thickness of the aluminum oxide layer is 3-10 nm.

The invention utilizes the different properties of two metals, namely the ability of aluminum and tungsten in bonding with oxygen ions, and the obtained resistive random access memory has more stable performances, lower power consumption and larger high resistance-low resistance ratio.

The additional aspects and the advantages of the invention will be given in part in the following description, and part of them will become apparent from the following description or be known by practices of the invention.

### DESCRIPTION OF THE DRAWINGS

The above and/or the additional aspects and the advantages of the invention will become apparent and easy to understand in the following description of embodiments in conjunctions with the drawings, wherein,

FIG. 1 is a structure schematic diagram of an Al-W-O stack structure applicable to a resistive random access memory according to an embodiment of the invention;

FIG. 2 is a transmission electron micrograph diagram of the Al-W-O stack structure applicable to the resistive random access memory according to the embodiment of the invention.

### DETAILED DESCRIPTION OF THE EMBODIMENTS

The embodiments of the invention are described below in detail, and the examples of the embodiments are shown in the drawings, wherein identical or similar reference numerals throughout the specification denote identical or similar elements or the elements with identical or similar functions. The embodiments described with reference to the drawings are exemplary, and they aim at illustrating the invention and should not be interpreted as limiting the invention.

In the description of the invention, it should be understood that the direction or position relations indicated by the terms “center”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise” and the like are the direction or position relations shown in the drawings, and are merely used for facilitating the description of the invention and simplifying the description rather than indicating or implying that the indicated devices or elements must be in specific directions, be constructed and operated in the specific directions, so that the terms can not be interpreted as limiting the invention. In addition, the terms “first” and “second” are only used for the purpose of description and should not be interpreted as indicating or implying the relative importance or implicitly indicating the number of the indicated technical features. Therefore, the features defining “first” and “second” can clearly or implicitly include one or more of the features. In the description of the invention, “more” means two or more unless otherwise specifically limited.

In the invention, unless otherwise clearly specified and limited, the terms “mounting”, “connected”, “connection”, “fixing” and the like should be understood in a broad sense. For example, the connection can be fixed connection, detachable connection or integrated connection; the connection can be mechanical connection or electrical connection; and the connection can be direct connection, indirect connection through an intermediate medium or internal communication of two elements. For those ordinary skilled in the art, the specific meanings of the terms in the invention can be understood according to specific situations.

In the invention, unless otherwise clearly specified and limited, the description that the first feature is “above” or “below” the second feature can include the direct contact between the first feature and the second feature and can also include the contact between the first and second features through another feature between them but not the direct contact. Furthermore, the description that the first feature is arranged “over”, “above” and “on” the second feature comprises the situation that the first feature is arranged just above or aslant above the second feature or only indicates that the horizontal height of the first feature is higher than that of the second feature. The description that the first feature is arranged “under”, “below” and “underneath” the second feature comprises the situation that the first feature is arranged just below or aslant below the second feature or only indicates that the horizontal height of the first feature is lower than that of the second feature.

In relation to the issue mentioned in the background of the invention that the operation voltage, the high resistance-low resistance ratio, the number of write-erase cycles and other performances of the resistive random access memories can be improved by selecting different material combinations, the invention provides an Al-W-O stack structure applicable to a resistive random access memory.

The core idea of the technical scheme of the invention is as follows: two metals, namely aluminum and tungsten are selected for stacking double metal oxide layers, wherein tungsten oxide is thicker, about 50 nm thick and being as the lower layer; and aluminum oxide is thinner in thickness, about 5 nm thick, manufactured by a contact type oxidation process as the upper layer. The invention utilizes the different properties of two metals, namely aluminum and tungsten in bonding with oxygen ions, and obtains a resistive random access memory with more stable performances, lower power consumption and larger high resistance-low resistance ratio.

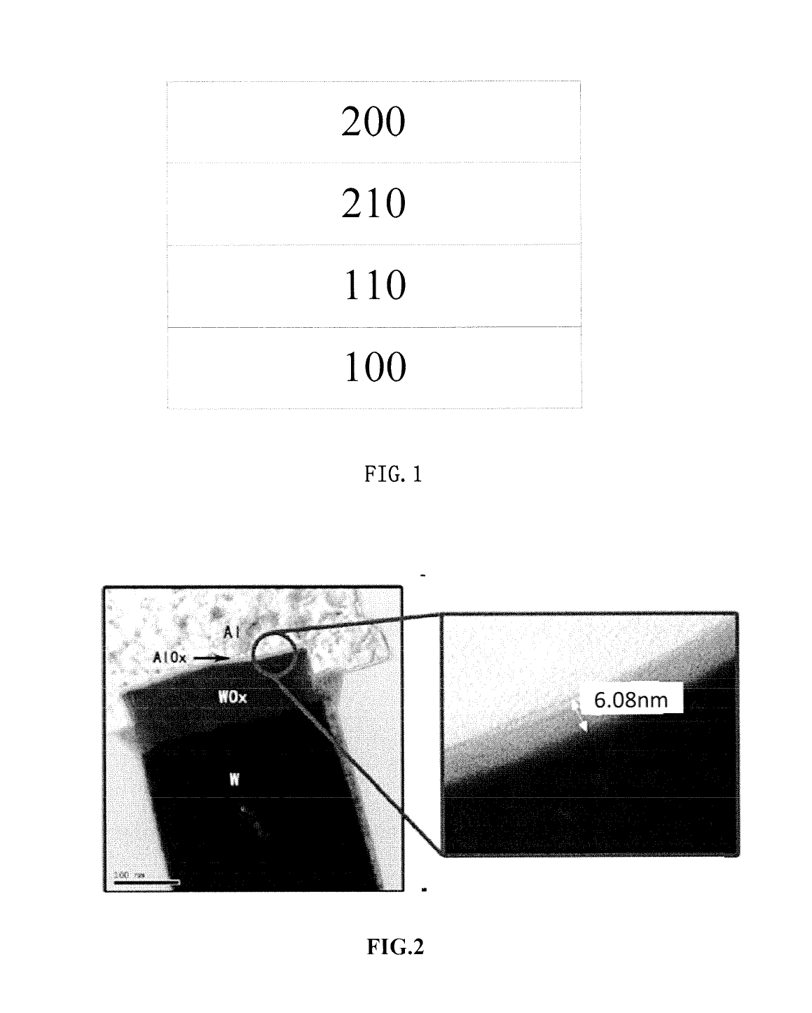

FIG. 1 is a structure schematic diagram of an Al-W-O stack structure applicable to a resistive random access memory according to an embodiment of the invention, and as shown in the figure, the Al-W-O stack structure applicable to the resistive random access memory according to the embodiment of the invention comprises a tungsten bottom electrode 100, a tungsten oxide layer 110 formed on the tungsten bottom electrode 100, an aluminum oxide layer 210 formed on the tungsten oxide layer 110 and an aluminum top electrode 200 formed on the aluminum oxide layer 210.

In one embodiment of the invention, the tungsten oxide layer 110 is formed in a thermal oxidation way.

In one embodiment of the invention, the thickness of the tungsten oxide layer 110 is 30-70 nm, preferably 50 nm. Under the condition of maintaining process and device stability, the roughness of tungsten oxide should be as smaller as possible.

In one embodiment of the invention, the aluminum oxide layer 210 is formed in a contact type oxidation way.

In one embodiment of the invention, the temperature of contact type oxidation is 400-500° C., and the time is 50-200 s.

In one embodiment of the invention, the thickness of the second oxide layer 210, i.e. the aluminum oxide layer 210 is 3-10 nm, preferably 5 nm. If the thickness of the second oxide layer 210 is too thin, the double-layer resistive switching performance will not exist, and if the thickness is too thick, the resistance value will be too large, and the resistive switching operation can not be performed.

In order to enable those skilled in the art to understand the invention better, the formation method of the Al-W-O stack structure of the invention is now presented as follows: metal tungsten is selected as the lower layer, whose thickness is larger. Firstly, the tungsten oxide layer which is about 50 nm thick is obtained on the metal tungsten lower electrode in a thermal oxidation way; then, a layer of metal aluminum is manufactured as an upper electrode on the tungsten oxide layer in an evaporation deposition way; and finally, an ultra-thin aluminum oxide layer which is about 5 nm thick is obtained by adopting a contact type oxidation technique, wherein a fast thermal annealing process is used in the contact type oxidation method. with the different attractive forces of aluminum and tungsten against oxygen atoms, the metal aluminum layer can capture oxygen atoms from the oxygen-rich tungsten oxide layer so as to form the ultra-thin stacked aluminum oxide layer.

FIG. 2 is a transmission electron micrograph diagram of the Al-W-O stack structure applicable to the resistive random access memory according to an embodiment of the invention, showing the thickness of each layer of the ultra-thin stacked and mixed oxide layers of Al-W-O.

In the description of the Specification, the description with reference to terms “one embodiment”, “some embodiments”, “example”, “specific example”, “some examples” or the like means that the specific features, the structure, the materials or the features described in conjunction with the embodiment or the example are/is encompassed in at least one embodiment or example of the invention. In the Specification, the schematic representation of the terms does not necessarily refer to the identical embodiment or example. Furthermore, the described specific features, structure, materials or characteristics can be combined in one or more embodiments or examples in an appropriate way.

Although the embodiments of the invention have been illustrated and described above, it can be understood that the embodiments are exemplary and can not be construed as limiting the invention; and those ordinary skilled in the art can make changes, modifications, substitutions and variations to the embodiments within the scope of the invention without departing from the principle and purpose of the invention.

We claim:

1. An Al-W-O stack structure applicable to a resistive random access memory, comprising:
a tungsten bottom electrode;
a tungsten oxide layer formed on the tungsten lower electrode;
an aluminum oxide layer formed on the tungsten oxide layer; and
an aluminum top electrode formed on the aluminum oxide layer.

2. The Al-W-O stack structure applicable to the resistive random access memory according to claim 1, characterized in that the tungsten oxide layer is formed in a thermal oxidation way.

3. The Al-W-O stack structure applicable to the resistive random access memory according to claim 1, characterized in that a thickness of the tungsten oxide layer is 30-70 nm.

4. The Al-W-O stack structure applicable to the resistive random access memory according to claim 1, characterized in that the aluminum oxide layer is formed in a contact type oxidation way.

5. The Al-W-O stack structure applicable to the resistive random access memory according to claim 1, characterized in that a temperature of the contact type oxidation is 400-500° C., and a time of the contact type oxidation is 50-200 s.

6. The Al-W-O stack structure applicable to the resistive random access memory according to claim 1, characterized in that a thickness of the aluminum oxide layer is 3-10 nm.
